(19) United States
(12) Patent Application Publication
(10) Pub. No.: US 2008/0048199 A1
(43) Pub. Date: Feb. 28, 2008

(54) Light emitting device and method of making the device

(76) Inventor: Kee Yean Ng, Penang (MY)

Correspondence Address: Kathy Manke;Avago Technologies Limited, 4380 Ziegler Road, Fort Collins, CO, 80525, US

(21) Appl. No.: 11/510,175

(22) Filed: Aug. 24, 2006

(51) Int. Cl. H01L 33/00

(52) U.S. Cl. 257/98

(57) ABSTRACT

A light emitting device and method of making the device uses an encapsulant to create a hollow region within a chamber of the device. The encapsulant is configured to contact at least a portion of a light source of the device and a portion of a lens of the device. The hollow region within the chamber provides space for the encapsulant to expand and contract.

### BACKGROUND OF THE INVENTION

Light emitting devices with optically transparent encapsulant, such as light emitting diodes (LEDs), are comprised of multiple components, which are packaged or integrated into a single unit. For an LED, these components may include an LED die, one or more bond wires, a plastic body, a substrate (which may be a leadframe or a printed circuit board), a lens and the encapsulant. The optical performance of the LED depends on the integrity of these packaged components. Thus, the integrity of the packaged components must be maintained to achieve proper and reliable optical performance throughout the operating lifetime of the LED.

One of the factors that can compromise the integrity of the packaged LED components is non-uniform thermal expansion of the components. The coefficient of thermal expansion (CTE) of the encapsulant is different than that of the LED die, the bond wire(s), the plastic body, the lens and the substrate. Due to this CTE mismatch, the encapsulant often becomes delaminated from other components of the LED over time, which subsequently leads to decrease in optical performance or even malfunction of the LED.

Several prior art approaches exist to address the encapsulant delamination problem in LEDs. One of the prior art approaches involves using an additive such as adhesion promoter in the encapsulant to increase the bond between the encapsulant and other components of the LED. Another prior art approach involves subjecting the substrate and the plastic body to a plasma cleaning step prior to dispensing the encapsulant, and also subjecting the lens to a plasma cleaning step prior to placing the lens on the plastic body.

A concern with the above prior art approaches is that they do not fully solve the problem of encapsulant delamination. Furthermore, these prior art approaches increase the manufacturing cost of the LEDs.

Another prior art approach to address the encapsulant delamination problem in LEDs involves removing the encapsulant entirely from the LEDs, resulting in “air-gap” devices. However, this prior art approach produces inferior LEDs since the light output is significantly reduced due to the low refractive index of air.

In view of the above-described concerns, there is a need for a light emitting device that alleviates the encapsulant delamination problem without compromising the light output of the device.

### SUMMARY OF THE INVENTION

A light emitting device and method of making the device uses an encapsulant to create a hollow region within a chamber of the device. The encapsulant is configured to contact at least a portion of a light source of the device and a portion of a lens of the device. The hollow region within the chamber provides space for the encapsulant to expand and contract, which reduces delamination of the encapsulant from the light source and/or the lens.

A light emitting device in accordance with an embodiment of the invention comprises a base structure, a lens, a chamber, a light source and an encapsulant. The lens is positioned over the base structure. The chamber is formed by at least the base structure and the lens. The light source is positioned over the base structure in the chamber. The light source is configured to generate light. The encapsulant is configured to contact at least a portion of lens and at least a portion of the light source. The encapsulant is further configured to create a hollow region in the chamber to provide space for the encapsulant to expand and contract within the chamber.

A method of making a light emitting device in accordance with an embodiment of the invention comprises providing a base structure, a light source, a lens and an optically transparent substance, and assembling the base structure, the light source and the lens such that a chamber is formed by at least the base structure and the lens in which the light source is positioned. The assembling includes forming an encapsulant in the chamber using the optically transparent substance to create a hollow region in the chamber to provide space for the encapsulant to expand and contract. The encapsulant is formed to contact at least a portion the lens and at least a portion of the light source.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a diagram of a light emitting device in accordance with an embodiment of the invention.

FIG. 2 is a diagram of a light emitting device in accordance with another embodiment of the invention.

FIG. 3 is a diagram of a light emitting device in accordance with another embodiment of the invention.

FIG. 4 is a diagram of a light emitting device in accordance with another embodiment of the invention.

FIG. 5 is a diagram of a light emitting device in accordance with another embodiment of the invention.

FIG. 6 is a flow diagram of a method of making a light emitting device in accordance with an embodiment of the invention.

### DETAILED DESCRIPTION

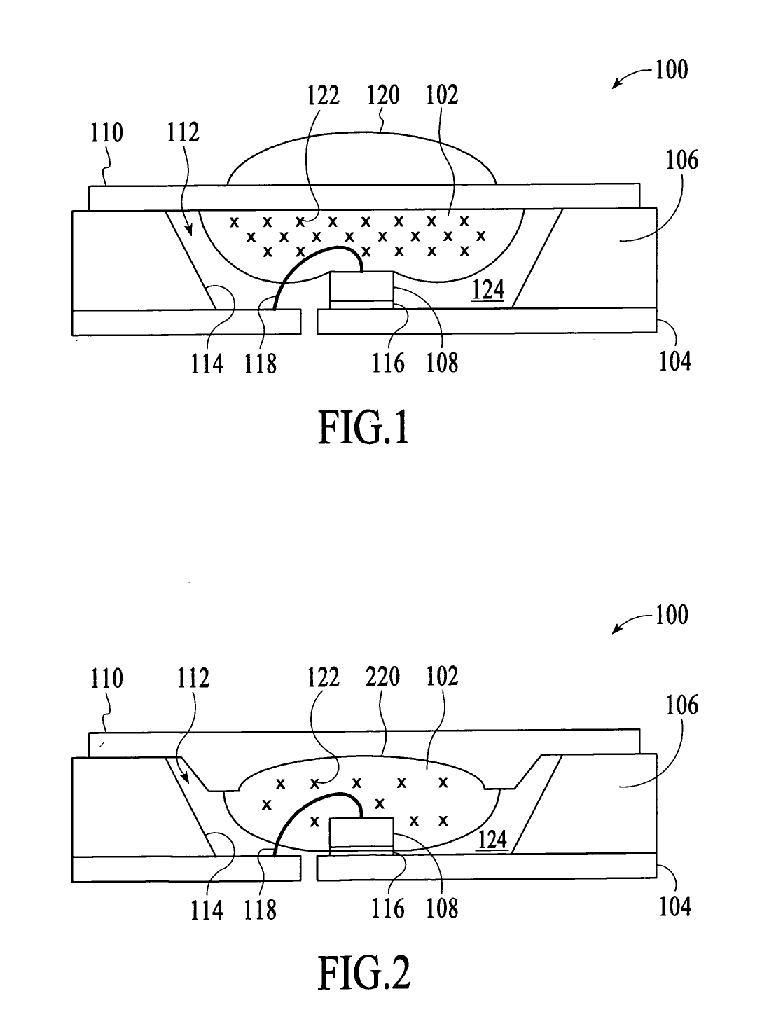

With reference to FIG. 1, a light emitting device 100 in accordance with an embodiment of the invention is shown. As described in more detail below, the light emitting device 100 is configured to reduce the likelihood of encapsulant delamination by providing space for an encapsulant 102 to expand and contract during extreme temperatures. Thus, the long term reliability of the light emitting device 100 is improved. Furthermore, the manufacturing process of the light emitting device 100 is simplified when compared to comparable conventional light emitting devices, which results in reduced manufacturing cost.

As shown in FIG. 1, the light emitting device 100 comprises a base structure (104, 106), a light emitting semiconductor die 108, a lens 110 and the encapsulant 102. In this embodiment, the base structure (104, 106) is a combination of a substrate 104 and a body 106. The substrate 104 provides a foundation for the light emitting device 100. The substrate 104 may be a leadframe, a printed circuit board or any other suitable substrate for the light emitting device 100. The body 106 is attached to the upper surface of the substrate 104, and thus, is positioned over the substrate. In this embodiment, the body 106 is composed of a plastic material. However, in other embodiments, the body 106 may be composed of any other suitable material. The body 106 includes a cavity 112 that extends from the top surface of the body down to the bottom surface of the body, exposing a portion of the upper surface of the substrate 104. In this embodiment, the cavity 112 is circular in shape when viewed from above. However, in other embodiments, the cavity 112 may be configured in a different shape, such as a rectangular shape. The cavity 112 includes a side surface or a sidewall 114 that is angled away from the center of the cavity.

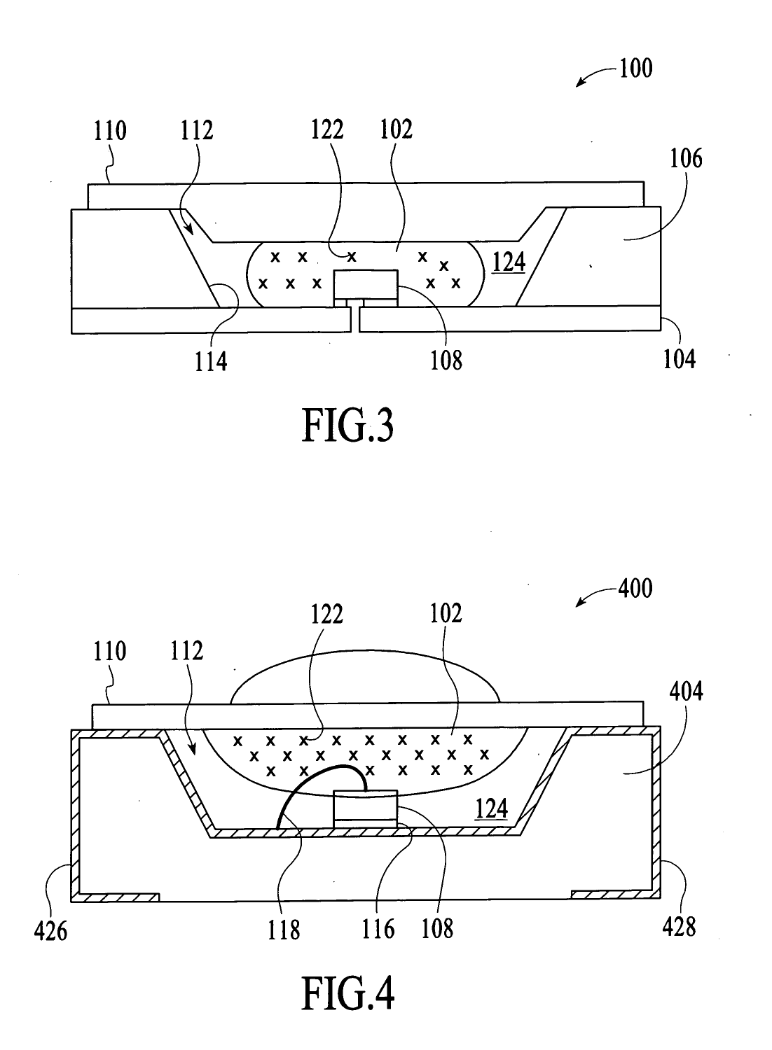

The light emitting semiconductor die 108 is mounted on the upper surface of the substrate 104 in the cavity 112. In this embodiment, the light emitting semiconductor die 108 is a light emitting diode (LED) die, and thus, the light emitting device 100 is an LED. In particular, the semiconductor die 108 is an LED die that is configured to emit most of the output light from its top surface. However, in other embodiments, the light emitting semiconductor die 108 may be any type of light emitting semiconductor die, such as a laser diode die. In this embodiment, the semiconductor die 108 is mounted to one part of the substrate using an adhesive material 116, which is also electrically conductive. The semiconductor die 108 is also electrically connected to another part of the substrate 104 via a bond wire 118. However, in other embodiments, the semiconductor die 108 may be electrically connected to different parts of the substrate 104 using two bond wires (not shown). Still, in other embodiments, the semiconductor die 106 may be mounted on the substrate 104 using flip chip technology, which would not require the bond wire 114, as illustrated in FIG. 3.

The lens 110 is attached to the body 106 over the cavity 112, which forms a chamber defined by the substrate 104, the lens 110 and the cavity sidewall 114 of the body 106. This chamber of the device 100 may be fully enclosed or substantially enclosed, i.e., there may be one or more small openings to the chamber. In the embodiment shown in FIG. 1, the lens 110 is a plano-convex type lens. Thus, the lower surface of the lens 110 that faces the semiconductor die 108 is substantially flat, while the upper surface of the lens that faces away from the semiconductor die includes a convex surface 120. In another embodiment, as illustrated in FIG. 2, the lens 110 is a plano-concave type lens. Thus, in this embodiment, the lower surface of the lens 110 includes a concave surface 220, while the upper surface of the lens is substantially flat. In another embodiment, as illustrate in FIG. 3, the lens 110 is a flat lens. Thus, in this embodiment, the lower and upper surfaces of the lens 110 are both substantially flat. In FIG. 3, the space between the lower surface of the lens 110 and the top surface of the semiconductor die 108 may be varied. In an embodiment, the lower surface of the lens 110 may essentially touch or contact the top surface of the semiconductor die 108 such that the thickness of the encapsulant 102 between the lens and the semiconductor die is negligible.

The encapsulant 102 is disposed in the cavity 112 of the body 106. The encapsulant 102 is composed of an optically transparent substance, which can be epoxy, silicone, a hybrid of silicone and epoxy, amorphous polyamide resin or fluorocarbon, glass and/or plastic material. The encapsulant 102 may also include adhesion promoter additives. In some embodiments, the encapsulant 102 may include a wavelength conversion material 122, which may be composed of one or more different types of inorganic phosphors, one or more different types of organic phosphors, one or more different types of fluorescent organic dyes, one or more different types of hybrid phosphors, one or more different types of nano-phosphors, one or more different types of quantum dots or any combination of fluorescent organic dyes, inorganic phosphors, organic phosphors, hybrid phosphors, nano-phosphors and quantum dots. A hybrid phosphor is defined herein as a phosphor made of any combination of inorganic phosphors and organic phosphors or dyes. Quantum dots, which are also known as semiconductor nanocrystals, are artificially fabricated devices that confine electrons and holes. Quantum dots have a photoluminescent property to absorb light and re-emit different wavelength light, similar to non-quantum phosphors. However, the color characteristics of emitted light from quantum dots depend on the size of the quantum dots and the chemical composition of the quantum dots, rather than just chemical composition as non-quantum phosphors. Nano-phosphors have similar optical properties as conventional phosphors. However, nano-phosphors are smaller in size than conventional phosphors, but larger than quantum dots. The size of conventional phosphors is in the range of 1-50 microns (typically in the 1-20 micron range). The size of nano-phosphors is smaller than 1 micron, but larger than quantum dots, which may be a few nanometers in size.

The optional wavelength conversion material 122 is used to convert at least some of the light emitted from the semiconductor die 108 into different wavelength light. Thus, the optional wavelength conversion material 122 can be used to change the color of the light emitted from the semiconductor die 108. However, the optional wavelength conversion material 122 can more commonly be used to produce white color light by mixing the converted light with the original light emitted from the semiconductor die 108. As an example, the wavelength conversion material 122 may be a conventional YAG phosphor, which when used with a blue-emitting LED die can produce white color light.

The encapsulant 102 is configured to form a contiguous region in the cavity 112 of the body 106. In the embodiment shown in FIG. 1, the encapsulant 102 is configured to contact the entire upper surface of the semiconductor die 108 and majority of the lower surface of the lens 110 over the cavity 112. Thus, the encapsulant 102 functions as a medium on which the light emitted from the semiconductor die 108 can travel to reach the lens 110 and be output through the lens. In the illustrated embodiment, the encapsulant 102 is configured to not contact the sidewall 114 of the cavity 112 and to not contact the upper surface of the substrate 104, forming a hollow region 124 between the encapsulant and both the sidewall of the cavity and the upper surface of the substrate. In an alternative embodiment, the encapsulant 102 may be configured to contact a small portion of the sidewall 114 of the cavity 112, which may reduce the hollow region 124 in the cavity without eliminating the entire hollow region. The hollow region 124 provides a space for the encapsulant 102 to expand and contract during extreme temperatures, which reduces stress at the interface between the encapsulant and the semiconductor die 108 and the interface between the encapsulant and the lens 110. Consequently, the encapsulant delamination problem is eliminated or significantly reduced for the light emitting device 100. In an embodiment, the hollow region 124 is filled with air. However, in other embodiments, the hollow region 124 may be filled with other gases. The hollow region 124 may occupy anywhere from 5% to 100% of the chamber defined by the substrate 104, the lens 110 and the cavity sidewall 114 of the body 106.

In other embodiments, the encapsulant 102 may be configured to contact or cover more of the semiconductor die 108. In an embodiment shown in FIG. 2, the encapsulant 102 is configured to contact most of the lower surface of the lens 110 over the cavity 112 and mostly encapsulate the semiconductor die 108 without contacting the upper surface of the substrate 104. In an embodiment shown in FIG. 3, the encapsulant 102 is configured to contact most of the lower surface of the lens 110 over the cavity 112 and fully encapsulate the semiconductor die 108 such that the encapsulant contacts a portion of the upper surface of the substrate 104. As illustrated in FIG. 2, if the lens 110 is a plano-concave type lens, the encapsulant 102 may fully fill the concave surface 220.

Turing now to FIG. 4, a light emitting device 400 in accordance with another embodiment of the invention is shown. Similar to the light emitting device 100 of FIGS. 1-3, the light emitting device 400 includes the light emitting semiconductor die 108, the lens 110 and the encapsulant 102. However, in this embodiment, the light emitting device 400 includes an integrated base structure 404, which replaces the substrate 104 and the body 106 of the device 100. Thus, in this embodiment, the substrate 104 and the body 106 have been integrated into a single structure. Consequently, the integrated base structure 404 may have the same structural configuration as the substrate 104 and the body 106 of the device 100. In particular, the integrated base structure 404 is configured to include the cavity 112. Thus, a chamber that contains the encapsulant 102 and the hollow region 124 is formed and defined by the cavity 112 of the integrated base structure 404 and the lens 110. This chamber of the device 400 may be fully enclosed or substantially enclosed, i.e., there may be one or more small openings to the chamber. The integrated base structure 404 can be made of any material, such as a ceramic or plastic material.

The light emitting device 400 also includes electrical terminals 426 and 428, which are positioned on the surface of the integrated base structure 404. As an example, the electrical terminals 426 and 428 may be plated onto the surface of the integrated base structure 404. The electrical terminals 426 and 428 serve as electrical paths to provide driving signals to the semiconductor die 108.

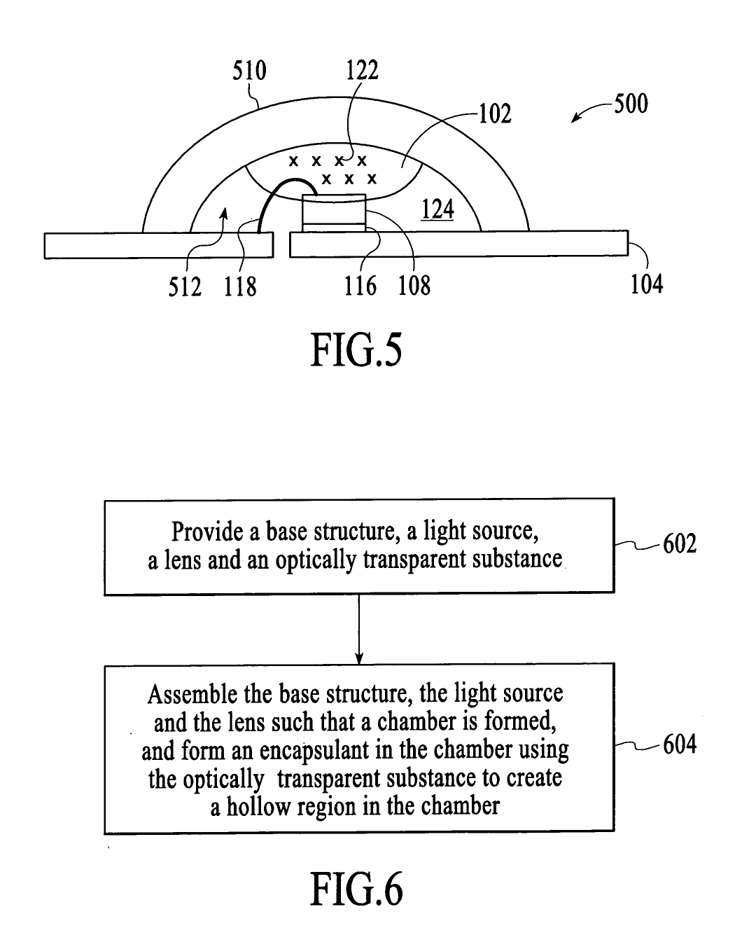

Turning now to FIG. 5, a light emitting device 500 in accordance with another embodiment of the invention is shown. Similar to the light emitting device 100 of FIGS. 1-3, the light emitting device 500 includes the substrate 104, the light emitting semiconductor die 108 and the encapsulant 102. However, in this embodiment, the light emitting device 500 does not include the body 106. Rather, the lighting emitting device 500 includes a lens 510, which is positioned on the upper surface of the substrate 104, as shown in FIG. 5. The lens 510 is configured to have a cavity 512, which is positioned over the semiconductor die 108. Thus, a chamber that contains the encapsulant 102 and the hollow region 124 is formed and defined by the substrate 104 and the lens 510. This chamber of the device 500 may be fully enclosed or substantially enclosed, i.e., there may be one or more small openings to the chamber. The shape of the lens 510 can be of any configuration. As an example, a portion of the lens 510 may be configured as a plano-convex type lens, a plano-concave type lens or a flat lens.

A method of making a light emitting device in accordance with an embodiment of the invention is described with reference to FIG. 6. At block 602, a base structure, a light source, a lens and an optically transparent substance are provided. The base structure may include a substrate, which may be a leadframe, a printed circuit board or any other suitable substrate for the light emitting device. The light source may be a light emitting semiconductor die, such as an LED die or a laser diode die. The lens may be a plano-convex type lens, a plano-concave type lens or a flat lens. The optically transparent substance may be epoxy, silicone, a hybrid of silicone and epoxy, amorphous polyamide resin or fluorocarbon, glass and/or plastic material. Next, at block 604, the base structure, the light source and the lens are assembled such that a chamber is formed by at least the base structure and the lens in which the light source is positioned. In addition, at block 604, an encapsulant is formed in the chamber using the optically transparent substance to create a hollow region in the chamber to provide space for the encapsulant to expand and contract within the chamber. The encapsulant is formed to contact at least a portion of the lens and at least a portion of the light source.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A light emitting device comprising:
a base structure;
a lens positioned over said base structure;
a chamber formed by at least said base structure and said lens;
a light source positioned over said base structure in said chamber, said light source being configured to generate light; and
an encapsulant disposed in said chamber, said encapsulant being configured to contact at least a portion of said lens and at least a portion of said light source, said encapsulant being further configured to create a hollow region in said chamber to provide space for said encapsulant to expand and contract within said chamber.

2. The device of claim 1 wherein said base structure comprises a substrate and a body including a cavity having a side surface, said body being positioned over said substrate, said cavity of said body partially defining said chamber.

3. The device of claim 2 wherein said substrate is one of a leadframe and a printed circuit board.

4. The device of claim 2 wherein said encapsulant is configured to not contact said side surface of said cavity of said body.

5. The device of claim 1 wherein said base structure includes a cavity having a side surface, said light source being positioned in said cavity, said chamber being partially defined by said cavity of said base structure.

6. The device of claim 5 wherein said encapsulant is configured to not contact said side surface of said cavity.

7. The device of claim 1 wherein said base structure is a substrate on which said light source is positioned and wherein said lens includes a cavity, said lens being positioned on an upper surface of said substrate, said chamber being defined by said cavity of said lens and said substrate.

8. The device of claim 7 wherein said substrate is one of a leadframe and a printed circuit board.

9. The device of claim 1 wherein said encapsulant is configured to encapsulate said light source and to contact an upper surface of said base structure.

10. The device of claim 1 wherein said encapsulant is configured to completely cover a top surface of said light source.

11. The device of claim 1 wherein said light source is a light emitting diode (LED) die.

12. The device of claim 1 wherein said encapsulant includes a wavelength conversion material.

13. The device of claim 1 wherein said lens includes one of a plano-convex type lens, a plano-concave type lens and a flat lens.

14. A method of making a light emitting device, said method comprising;
providing a base structure, a light source, a lens and an optically transparent substance; and
assembling said base structure, said light source and said lens such that a chamber is formed by at least said base structure and said lens in which said light source is positioned, including forming an encapsulant in said chamber using said optically transparent substance to create a hollow region in said chamber to provide space for said encapsulant to expand and contract, said encapsulant being formed to contact at least a portion of said lens and at least a portion of said light source.

15. The method of claim 14 wherein said base structure comprises a substrate and a body including a cavity having a side surface and wherein said assembling includes positioning said body over said substrate, said cavity of said body partially defining said chamber.

16. The method of claim 15 wherein said encapsulant is formed to not contact said side surface of said cavity of said body.

17. The method of claim 14 wherein said base structure includes a cavity having a side surface, said chamber being partially defined by said cavity of said base structure.

18. The method of claim 14 wherein said base structure is a substrate, said lens includes a cavity and said assembling includes positioning said lens on an upper surface of said substrate, said chamber being defined by said cavity of said lens and said substrate.

19. The method of claim 14 wherein said encapsulant is formed to encapsulate said light source and to contact said base structure.

20. The method of claim 14 wherein said encapsulant is formed to completely cover a top surface of said light source.
